(19) United States
(12) Patent Application Publication
(10) Pub. No.: US 2025/0253246 A1
(43) Pub. Date: Aug. 7, 2025

(54) SEMICONDUCTOR DEVICE AND METHOD FOR FORMING THE SAME

(71) Applicant: TAIWAN SEMICONDUCTOR MANUFACTURING COMPANY, LTD., Hsinchu (TW)

(72) Inventors: Han YEH, Hsinchu County (TW); Yu-Lien HUANG, Hsinchu County (TW); Yuan-Sheng HUANG, Taichung City (TW); Yung-Cheng LU, Hsinchu City (TW)

(73) Assignee: TAIWAN SEMICONDUCTOR MANUFACTURING COMPANY, LTD., Hsinchu (TW)

(21) Appl. No.: 18/434,215

(22) Filed: Feb. 6, 2024

(51) Int. Cl. H01L 23/532; H01L 21/02; H01L 29/40; H01L 29/417

(52) U.S. Cl. CPC H01L 23/53295; H01L 21/0217; H01L 21/0228; H01L 21/02315; H10D 64/01; H01L 21/02211; H10D 64/258

(57) ABSTRACT

A semiconductor device includes a substrate. A gate structure is over the substrate. Source/drain epitaxial structures are on opposite sides of the gate structure. An interlayer dielectric (ILD) structure surrounds and covers the gate structure. A dielectric liner lines a sidewall of the ILD structure and wraps a top corner of the gate structure. The dielectric liner comprises a bottom portion, a top portion above the bottom portion, and a middle portion connecting the bottom portion and the top portion, wherein the middle portion has a different composition than the bottom portion and the top portion.

### BACKGROUND

The semiconductor integrated circuit (IC) industry has experienced rapid growth. Technological advances in IC materials and design have produced generations of ICs. Each generation has smaller and more complex circuits than the previous generation. However, these advances have increased the complexity of processing and manufacturing ICs. In the course of IC evolution, functional density (i.e., the number of interconnected devices per chip area) has generally increased while geometric size (i.e., the smallest component (or line) that can be created using a fabrication process) has decreased. This scaling-down process generally provides benefits by increasing production efficiency and lowering associated costs. However, since feature sizes continue to decrease, fabrication processes continue to become more difficult to perform. Therefore, it is a challenge to form reliable semiconductor devices at smaller and smaller sizes.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1 to 8 illustrate a method for manufacturing a semiconductor device at various stages in accordance with some embodiments of the present disclosure.

FIGS. 9A to 9D illustrate a method of an area selective deposition process at various stages in accordance with some embodiments of the present disclosure.

FIGS. 10 to 13 illustrate a method for manufacturing a semiconductor device at various stages in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. As used herein, “around,” “about,” “approximately,” or “substantially” may generally mean within 20 percent, or within 10 percent, or within 5 percent of a given value or range. Numerical quantities given herein are approximate, meaning that the term “around,” “about,” “approximately,” or “substantially” can be inferred if not expressly stated. One skilled in the art will realize, however, that the values or ranges recited throughout the description are merely examples, and may be reduced or varied with the down-scaling of the integrated circuits.

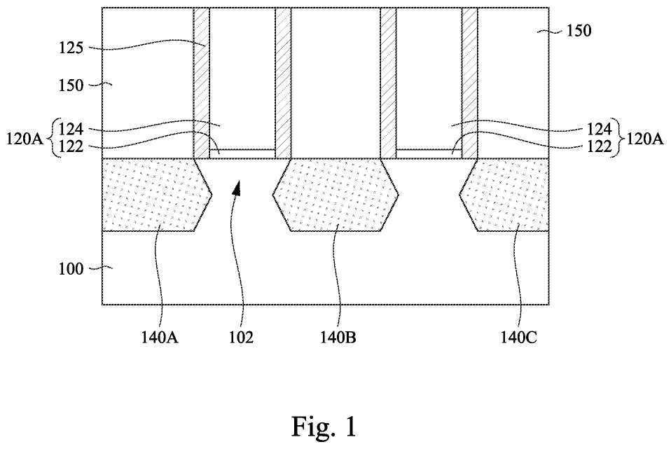

FIGS. 1 to 8 illustrate a method for manufacturing a semiconductor device at various stages in accordance with some embodiments of the present disclosure. Although the views shown in FIGS. 1 to 8 are described with reference to a method, it will be appreciated that the structures shown in FIGS. 1 to 8 are not limited to the method but rather may stand alone separate of the method. Although FIGS. 1 to 8 are described as a series of acts, it will be appreciated that these acts are not limiting in that the order of the acts can be altered in other embodiments, and the methods disclosed are also applicable to other structures. In other embodiments, some acts that are illustrated and/or described may be omitted in whole or in part.

Reference is made to FIG. 1. Shown there is a substrate 100. The substrate 100 may be a semiconductor substrate, such as a bulk semiconductor, a semiconductor-on-insulator (SOI) substrate, or the like. The substrate 100 may be a wafer, such as a silicon wafer. Generally, an SOI substrate includes a layer of a semiconductor material formed on an insulator layer. The insulator layer may be, for example, a buried oxide (BOX) layer, a silicon oxide layer, or the like. The insulator layer is provided on a substrate, a silicon or glass substrate. Other substrates, such as a multi-layered or gradient substrate may also be used. In some embodiments, the semiconductor material of the substrate 100 may include silicon; germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof.

In some embodiments, a semiconductor fin 102 may be formed over the substrate 100. The semiconductor fin 102 may be formed by, for example, forming a mask layer over the substrate 100, the mask layer including openings that expose portions of the substrate 100. The exposed substrate 100 is then etched through the openings of the mask layer, forming trenches in the substrate 100. A portion of the substrate 100 between neighboring trenches can be referred to as the semiconductor fin. Isolation structures (not shown) may be formed over the substrate 100 and laterally surrounding bottom portions of the semiconductor fin 102. The isolation structures can be referred to as shallow trench isolation (STI) structures. In some embodiments, the isolation structures may be made of silicon oxide, silicon nitride, silicon oxynitride, or combinations thereof.

Dummy gate structures 120A and 120B are formed over the semiconductor fin 102 of the substrate 100. In some embodiments, each of the dummy gate structures 120A and 120B includes a dummy gate dielectric 122 and a dummy gate electrode 124 over the dummy gate dielectric 122. The dummy gate dielectric 122 may be, for example, silicon oxide, silicon nitride, a combination thereof, or the like, and may be deposited or thermally grown according to acceptable techniques. The dummy gate electrode 124 may be a conductive or non-conductive material and may be selected from a group including amorphous silicon, polycrystalline-silicon (polysilicon), polycrystalline silicon-germanium (poly-SiGe), metallic nitrides, metallic silicides, metallic oxides, and metals.

The dummy gate electrode 124 and the dummy gate dielectric 122 may be formed by, for example, depositing a dummy dielectric layer and a dummy gate layer over the substrate 100, forming patterned masks (not shown) over the dummy gate layer, and then performing an etching process to the dummy dielectric layer and the dummy gate layer by using the patterned masks as an etching mask. In some embodiments, the dummy gate electrode 124 may be deposited by physical vapor deposition (PVD), CVD, sputter deposition, or other techniques for depositing the selected material. In some embodiments, the dummy gate dielectric 122 may be formed by thermal oxidation.

Gate spacers 125 are formed on opposite sidewalls of each of the dummy gate structures 120A and 120B. The method of forming the gate spacers 125 includes blanket forming a dielectric layer over the substrate 100 using, for example, CVD, PVD or ALD, and then performing an etching process such as anisotropic etching to remove horizontal portions of the dielectric layer. The remaining portions of the dielectric layer on the sidewalls of the dummy gate structures 120A and 120B can serve as the gate spacers 125. In some embodiments, the gate spacers 125 may be used to offset subsequently formed source/drain regions. The gate spacers 125 may further be used for designing or modifying the source/drain region profile. In some embodiments, the gate spacers 125 may include silicon oxide, silicon nitride, silicon oxynitride, silicon carbide, silicon carbonitride, silicon oxycarbonitride, silicon oxycarbide, porous dielectric materials, hydrogen doped silicon oxycarbide (SiOC:H), low-k dielectric materials or other suitable dielectric material. The gate spacers 125 may include a single layer or multilayer structure made of different dielectric materials.

Portions of the semiconductor fin 102 exposed by the dummy gate structures 120A/120B and the gate spacers 125 are partially removed (or partially recessed) to form source/drain recesses. Source/drain epitaxial structures 140A, 140B, and 140C are formed in the source/drain recesses, respectively. In greater detail, as shown in the cross-sectional view of FIG. 1, the source/drain epitaxial structures 140A and 140B are formed on opposite sides of the dummy gate structure 120A, and the source/drain epitaxial structures 140B and 140C are formed on opposite sides of the dummy gate structure 120B. It is noted that, source/drain region(s) may refer to a source or a drain, individually or collectively dependent upon the context.

The source/drain epitaxial structures 140A, 140B, and 140C may be formed using one or more epitaxy or epitaxial (epi) processes, such that Si features, SiGe features, silicon phosphate (SiP) features, silicon carbide (SiC) features and/or other suitable features can be formed in a crystalline state over the substrate 100. The epitaxy processes include CVD deposition techniques (e.g., vapor-phase epitaxy (VPE) and/or ultra-high vacuum CVD (UHV-CVD)), molecular beam epitaxy, and/or other suitable processes. The source/drain epitaxial structures 140A, 140B, and 140C may be in-situ doped. The doping species include p-type dopants, such as boron or BF₂; n-type dopants, such as phosphorus or arsenic; and/or other suitable dopants including combinations thereof.

An interlayer dielectric (ILD) layer 150 is formed over the substrate 100 and covering the source/drain epitaxial structures 140A, 140B, and 140C. Afterwards, a CMP process may be optionally performed to remove excess materials of the ILD layer 150 to expose the dummy gate structures 120A and 120B. The CMP process may planarize a top surface of the ILD layer 150 with top surfaces of the dummy gate structure 120A and 120B and the gate spacers 125.

In some embodiments, the ILD layer 150 may include silicon oxide, silicon nitride, silicon oxynitride, tetraethoxysilane (TEOS), phosphosilicate glass (PSG), borophosphosilicate glass (BPSG), low-k dielectric material, and/or other suitable dielectric materials. Examples of low-k dielectric materials include, but are not limited to, fluorinated silica glass (FSG), carbon doped silicon oxide, amorphous fluorinated carbon, parylene, bis-benzocyclobutenes (BCB), or polyimide. The ILD layer 150 may be formed using, for example, CVD, ALD, spin-on-glass (SOG) or other suitable techniques.

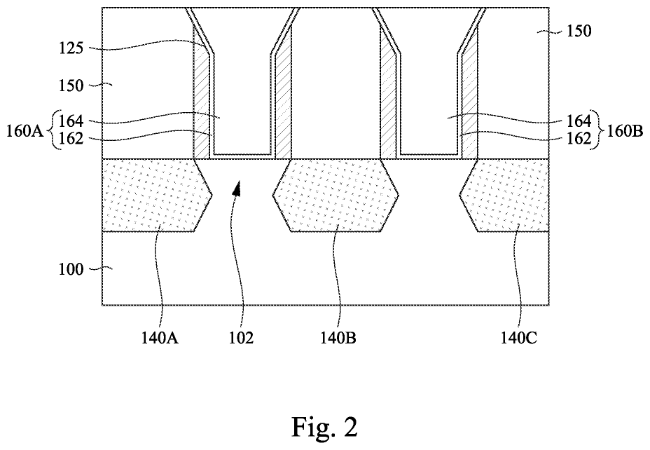

Reference is made to FIG. 2. The dummy gate structures 120A and 120B are replaced with metal gate structures 160A and 160B. The process can be referred to as a replacement gate (RPG) process. During the replacement gate process, the dummy gate structures 120A and 120B are removed to form gate trenches between each pair of the gate spacers 125. An etching process is performed to the gate spacers 125 to lower the top end of each of the gate spacers 125. During the etching process, portions of the ILD layer 150 may be removed, so as to form openings in the ILD layer 150, in which each opening is above the respective gate trench. In some embodiments, the opening may be wider than a distance between outer sidewalls of the gate spacers 125. This will facilitate the gap-fill capability of forming the metal gate structures 160A and 160B.

The metal gate structures 160A and 160B are then formed in the opening and the gate trench. Such process will result in that each of the metal gate structures 160A and 160B may include a T-shape cross-sectional profile. For example, each of the metal gate structures 160A and 160B may include a lower portion and a top portion wider than the lower portion. Moreover, the etched back gate spacers 125 may line the sidewalls of the lower portion of the respective metal gate structures 160A and 160B. In some embodiments, the top portions of the metal gate structures 160A and 160B are free of coverage, at least in part, by the gate spacers 125. In some embodiments, the top ends of the etched back gate spacers 125 may be lower than the topmost surfaces of the metal gate structures 160A and 160B. In some embodiments, the top surface of each of the metal gate structures 160A and 160B may be wider than the distance between outer sidewalls of the gate spacers 125. In some embodiments, the top portion of the metal gate structures 160A and 160B may be in contact with the ILD layer 150.

In some embodiments, each of the metal gate structures 160A and 160B may include a gate dielectric layer 162 and a gate metal 164. In some embodiments, the gate dielectric layer 162 may include an interfacial layer and a high-k dielectric layer over the interfacial layer. In some embodiments, the interfacial layer may be made of oxide, such as aluminum oxide (Al₂O₃), silicon oxide (SiO₂), or the like. Examples of high-k dielectric material include HfO₂, HfSiO, HfSiON, HfTaO, HfTiO, HfZrO, zirconium oxide, aluminum oxide, titanium oxide, hafnium dioxide-alumina (HfO₂—Al₂O₃) alloy, other suitable high-k dielectric materials, and/or combinations thereof.

The gate metal 164 may include work function metal layer(s) and a filling metal. The work function metal layer may be an n-type or p-type work function layer. Exemplary p-type work function metals include TiN, TaN, Ru, Mo, Al, WN, ZrSi₂, MoSi₂, TaSi₂, NiSi₂, WN, other suitable p-type work function materials, or combinations thereof. Exemplary n-type work function metals include Ti, Ag, TaAl, TaAlC, TiAlN, TaC, TaCN, TaSiN, Mn, Zr, other suitable n-type work function materials, or combinations thereof. The work function layer may include a plurality of layers. The filling metal may include tungsten (W), aluminum (Al), copper (Cu), or another suitable conductive material(s).

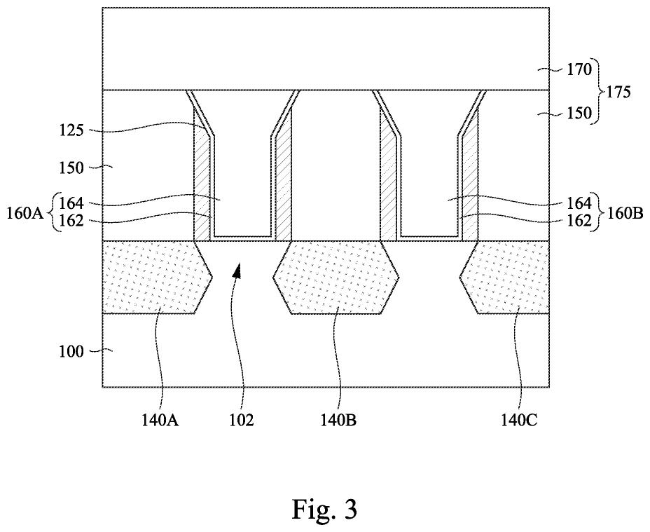

Reference is made to FIG. 3. An ILD layer 170 is formed over the ILD layer 150 and covering the metal gate structures 160A and 160B. In some embodiments, the ILD layer 170 may include silicon oxide, silicon nitride, silicon oxynitride, tetraethoxysilane (TEOS), phosphosilicate glass (PSG), borophosphosilicate glass (BPSG), low-k dielectric material, and/or other suitable dielectric materials. Examples of low-k dielectric materials include, but are not limited to, fluorinated silica glass (FSG), carbon doped silicon oxide, amorphous fluorinated carbon, parylene, bis-benzocyclobutenes (BCB), or polyimide. The ILD layer 170 may be formed using, for example, CVD, ALD, spin-on-glass (SOG) or other suitable techniques. In some embodiments, the ILD layers 150 and 170 can be collectively referred to as an ILD structure 175.

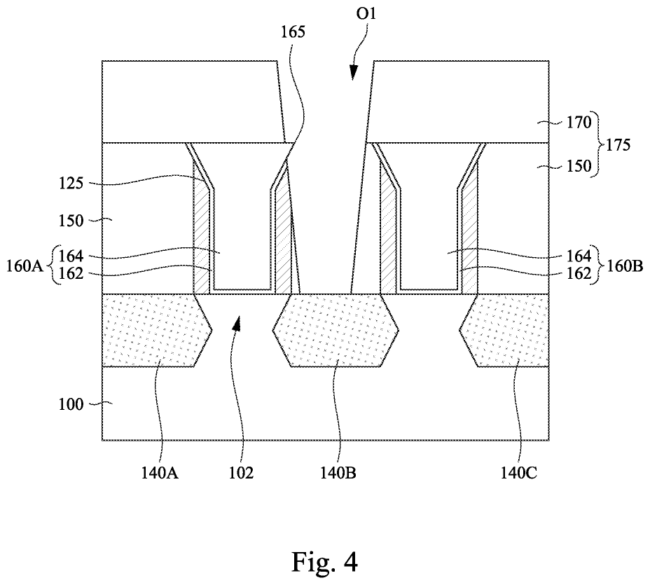

Reference is made to FIG. 4. A source/drain contact opening O1 is formed in the ILD structure 175, so as to expose the source/drain epitaxial structure 140B between the metal gate structures 160A and 160B. The source/drain contact opening O1 can be formed by, for example, forming a mask layer (e.g., photoresist) over the ILD structure 175, patterning the mask layer to form an opening in the mask layer, etching the ILD structure 175 through the opening of the mask layer until the source/drain epitaxial structure 140B is exposed, and then removing the mask layer. In some embodiments, during patterning the mask layer, overlay error may occur, such that the opening of the mask layer may shift toward one of the metal gate structures 160A and 160B.

In the embodiments of FIG. 4, the opening of the mask layer may shift toward the metal gate structure 160A, and thus the resulting source/drain contact opening O1 may shift toward the metal gate structure 160A, such that the source/drain contact opening O1 may be closer to the metal gate structure 160A than to the metal gate structure 160B. In some embodiments, the overlay error may result in that a portion of the metal gate structure 160A may be unwantedly exposed through the source/drain contact opening O1. For example, in FIG. 4, at least a top corner 165 of the gate metal 164 of the metal gate structure 160A is exposed to the source/drain contact opening O1. This is because the metal composition of the metal gate structure 160A may include higher etching resistance to the etching process for etching the ILD structure 175 than the dielectric material of the ILD structure 175. As a result, the top corner 165 of the gate metal 164 of the metal gate structure 160A may protrude from the ILD structure 175 and extend toward the source/drain contact opening O1. On the other hand, the metal gate structure 160B may not be exposed to the source/drain contact opening O1. That is, top corners of the metal gate structure 160B are still covered by the ILD structure 175 once the source/drain contact opening O1 is formed.

In some embodiments, during etching the ILD structure 175, portion of the gate dielectric layer 162 of the metal gate structure 160A may also be etched. This is because the dielectric material of the gate dielectric layer 162 may not include sufficient etching resistance to the etching process for etching the ILD structure 175.

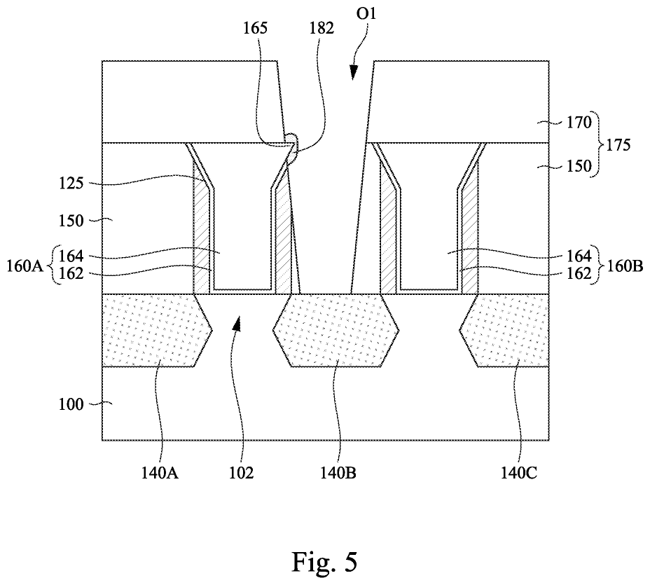

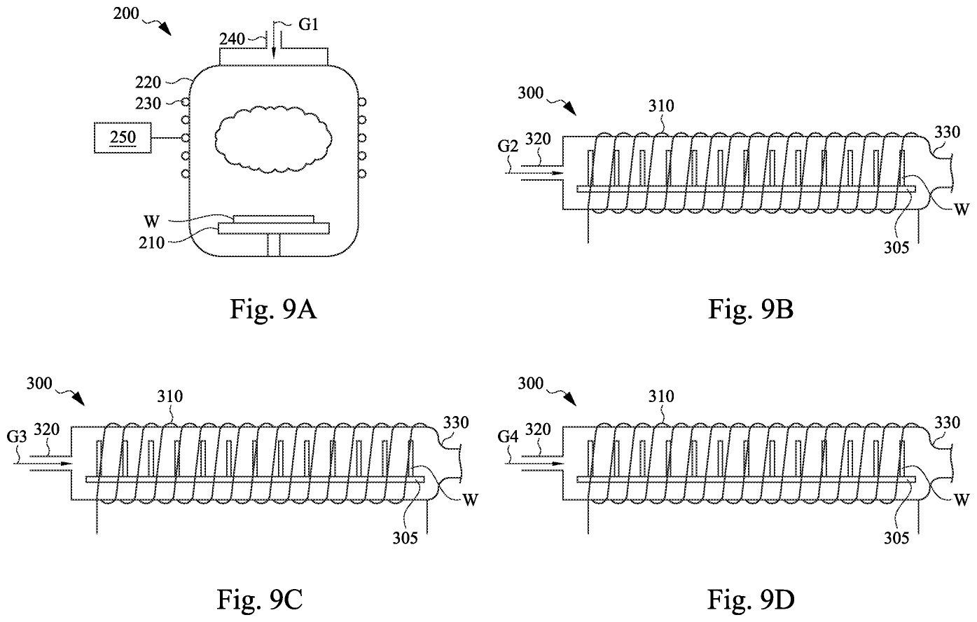

Reference is made to FIG. 5. An area selective deposition (ASD) process is performed to form a dielectric material 182 covering the exposed top corner 165 of the gate metal 164 of the metal gate structure 160A. In some embodiments, the dielectric material 182 may be made of silicon nitride (SiN). The ASD process is performed such that the dielectric material 182 is selectively deposited on the exposed surface of the top corner 165 of the gate metal 164 of the metal gate structure 160A. In greater detail, the material of the dielectric material 182 may include a higher deposition rate on a metal surface than on a dielectric surface. That is, the material of the dielectric material 182 may include a higher deposition rate on the exposed surface of the top corner 165 of the gate metal 164 of the metal gate structure 160A than on the exposed surface of the ILD structure 175 and/or the exposed surface of the gate dielectric layer 162 of the metal gate structure 160A. In some embodiments, the dielectric material 182 may include a ball-like cross-sectional view than wraps the top corner 165 of the gate metal 164 of the metal gate structure 160A. In some embodiments, a least a portion of the dielectric material 182 may extend to the surface of the ILD structure 175 and/or the surface of the gate dielectric layer 162 of the metal gate structure 160A. FIGS. 9A to 9D illustrate various steps of the ASD process for forming the dielectric material 182 of FIG. 5.

Reference is made to FIG. 9A. A surface treatment is performed to the structure shown in FIG. 4. The wafer W (including the structure shown in FIG. 4) is transferred to a wafer stage 210 of a plasma chamber 200. The plasma chamber 200 is configured to generate plasma, for example, through Inductively Coupled Plasma (ICP). The plasma chamber 200 includes a shower head 220 above the wafer stage 210, the shower head 220 is surrounded by a coil 230, and the shower head 220 includes a gas inlet 240 at the top of the shower head 220. An RF source 250 is coupled to the coil 230.

During the surface treatment, processing gas G1 including hydrogen gas (H₂) and oxygen gas (O₂) is supplied into the plasma chamber 200 through the gas inlet 240 of the shower head 220. Suitable RF power of the RF source 250 is supplied to the coil 230, and the temperature of the plasma chamber 200 is controlled, so as to generate hydrogen radical plasma (H*) and oxygen radical plasma (O*). Here, the term “radical” may be referred to as atom or molecule that has neutral charge. In some embodiments, the temperature of the surface treatment is less than 300° C., such as about 250° C. to about 300° C.

During the surface treatment as described in FIG. 9A, oxidation process and reduction process may occur at the same time but at different locations. In some embodiments, the exposed surfaces of the ILD structure 175 (see FIG. 4) may undergo an oxidation process during the surface treatment, while the exposed surface of the top corner 165 of the gate metal 164 of the metal gate structure 160A may undergo a reduction process. With respect to the oxidation process, the oxygen radicals may react with elements of the ILD structure 175. In some embodiments where the ILD structure 175 comprises silicon oxide, the oxygen radicals may react with the exposed silicon atoms on the surfaces of the ILD structure 175 to form a silicon oxide (SiO₂) layer along the exposed surfaces of the ILD structure 175, this will facilitate the ASD process and will be discussed later. With respect to the reduction process, during the manufacturing process, natural oxide (e.g., metal oxide) may be formed over the exposed surface of the top corner 165 of the gate metal 164 of the metal gate structure 160A. The hydrogen radicals may chemically react with the oxidized surface of the gate metal 164 by breaking M-O bonds (M denoted to metal atoms) at the surface of the gate metal 164. The oxygen atoms that are released away from the oxidized of the gate metal 164 may react with the hydrogen to produce water as a by-product, leaving the exposed surface of the gate metal 164 substantially a pure metal layer.

Reference is made to FIG. 9B. After the surface treatment of FIG. 9A is complete, a surface passivation is then performed. The wafer W (including the structure shown in FIG. 4) is transferred to a wafer stage 305 of a furnace 300. Here, the furnace 300 can also be referred to as a chamber that is different from the plasma chamber 200 described in FIG. 9A. The furnace 300 is surrounded by a coil 310, and the furnace 300 includes a gas inlet 320 and a gas outlet 330. The coil 310 is connected to an RF power (not shown) to control the temperature of the furnace 300.

During the surface passivation, processing gas G2 including tungsten hexafluoride gas (WF₆) and nitrogen gas (N₂) is supplied into the furnace 300 through the gas inlet 320. As mentioned above, during the surface treatment of FIG. 9A, the exposed surfaces of the ILD structure 175 are oxidized to form a silicon oxide (SiO₂) surface. The WF₆ gas may react with the silicon oxide (SiO₂) surface of the ILD structure 175 by replacing the Si—O bonds with Si—F bonds. The released oxygen atoms may react with the WF₆ gas to form tungsten oxytetrafluoride (WOF₄) gas, and may be pumped away through the gas outlet 330. The nitrogen gas (N₂) is used as carrier gas during the surface passivation. In some embodiments, the temperature of the surface passivation is less than 400° C., such as about 350° C. to about 400° C. The duration of the surface passivation is in a range from about 15 min and about 17 min, such as 16 min.

Reference is made to FIG. 9C. After the surface passivation of FIG. 9B is complete, an annealing process is then performed. The wafer W is kept in the furnace 300 for the annealing process. During the surface passivation, processing gas G3 including nitrogen gas (N₂) is supplied into the furnace 300 through the gas inlet 320. The annealing process is performed to reduce moisture (e.g., water, H₂O), in the structure shown in FIG. 4. In some embodiments, the temperature of the annealing process is less than 400° C., such as about 350° C. to about 400° C. The duration of the annealing process is in a range from about 50 min and about 70 min, such as 60 min.

Reference is made to FIG. 9D. After the annealing process of FIG. 9C is complete, a thermal atomic layer deposition (ALD) process is then performed, so as to form the dielectric material 182 selectively on the exposed surface of the top corner 165 of the gate metal 164 of the metal gate structure 160A. The wafer W is kept in the furnace 300 for the thermal ALD process, and processing gas G4 (e.g., precursors) for depositing the dielectric material 182 is supplied into the furnace 300 through the gas inlet 320. In some embodiments where the dielectric material 182 is made of silicon nitride (N₂), the precursors of the thermal ALD process may include a silicon source precursor and a nitrogen source precursor. The silicon source precursor may include SiH₂Cl₂, SiH₂I₂, the like, or combinations thereof. The nitrogen source precursor may include NH3, N2, the like, or combinations thereof. As mentioned above, the exposed surfaces of the exposed surfaces of the ILD structure 175 are oxidized to form a silicon oxide surface, and the silicon oxide surface is passivated by replacing the Si—O bonds at the silicon oxide surface with Si—F bonds. Because the Si—F bonds include stronger bonding energy, the precursors for depositing the dielectric material 182 are hard to react with the Si—F bonds at the surfaces of the ILD structure 175. Stated another way, the Si—F bonds at the surfaces of the ILD structure 175 may inhibit the deposition rate of the dielectric material 182. As a result, the Si—F bonds at the surfaces of the ILD structure 175 may act as inhibitors that block the surfaces of the ILD structure 175, such that the material of the dielectric material 182 may be selectively deposited on the exposed surface of the gate metal 164 of the metal gate structure 160A. Accordingly, the dielectric material 182 can be deposited in an area selective deposition manner, and the resulting structure is shown in FIG. 5. In some embodiments, the temperature of the annealing process is less than 400° C., such as about 350° C. to about 400° C. In some embodiments, the thickness of the dielectric material 182 is in a range from about 1 nm to about 5.05 nm.

In some embodiments, due to the thermal budget for the metal gate structures 160A and 160B, the process temperatures for forming the dielectric material 182 as described in FIGS. 9A to 9D are kept under 400° C. In some embodiments, the surface passivation of FIG. 9B, the annealing process of FIG. 9C, and the thermal ALD process of FIG. 9D are performed in the same furnace 300.

As mentioned above, as described in FIG. 9C, WF₆ gas is used as the reaction gas during the surface passivation. In some embodiments, some tungsten atoms (W) and fluorine atoms (F) may remain in the structure as shown in FIG. 5. For example, tungsten atoms (W) and fluorine atoms (F) may be detectable at the interface between the gate metal 164 of the metal gate structure 160A and the dielectric material 182. The above mentioned element concentration can be detected using energy dispersive X-ray (EDX) analysis.

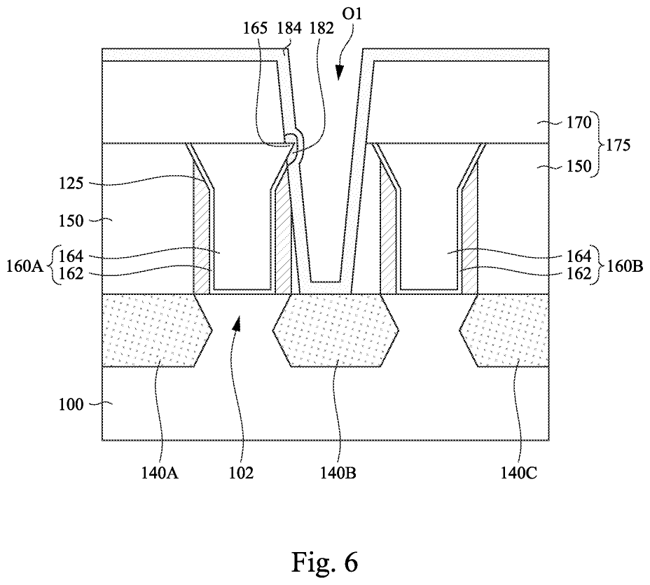

Reference is made to FIG. 6. A dielectric layer 184 is deposited over the substrate 100. In greater detail, the dielectric layer 184 is deposited in a conformal manner, such that the dielectric layer 184 is formed lining the exposed surfaces of the ILD structure 175, the exposed surface of the dielectric material 182, and the top surface of the source/drain epitaxial structure 140B. In some embodiments, the dielectric layer 184 may be spaced apart from the top corner 165 of the gate metal 164 of the metal gate structure 160A through the dielectric material 182. In some embodiments, the dielectric layer 184 may be formed using a plasma enhanced atomic layer deposition (PEALD) process. The dielectric layer 184 may be made of silicon nitride, silicon oxynitride, silicon carbide, silicon carbonitride, silicon oxycarbonitride, silicon oxycarbide, or the like.

In some embodiments, the dielectric layer 184 may be made of a same material as the dielectric material 182, such as silicon nitride, but are different in compositions. For example, the dielectric material 182 may include higher oxygen atomic concentration than the dielectric layer 184. In some embodiments, the oxygen atomic concentration of the dielectric material 182 is in a range from about 28% to about 35%, while the oxygen atomic concentration of the dielectric layer 184 is in a range from about 0% to about 0.3%. This is because the dielectric material 182 is deposited under a low temperature condition, and the dielectric material 182 may be formed having a porous structure. Once the structure leaves the deposition chamber, oxygen (air) may diffuse into the dielectric material 182.

Because WF₆ gas may be used during forming the dielectric material 182, the dielectric material 182 may include higher tungsten atomic concentration and higher fluorine atomic concentration than the dielectric layer 184. In some embodiments, the fluorine atomic concentration of the dielectric material 182 is in a range from about 0.2% to about 0.4%, while the fluorine atomic concentration of the dielectric layer 184 may be 0%.

Because SiH₂Cl₂ or SiH₂I₂ may be used during forming the dielectric material 182, the dielectric material 182 may include higher halogen atomic concentration (e.g., Cl or I) than the dielectric layer 184. In some embodiments, the chlorine atomic concentration of the dielectric material 182 is in a range from about 1.2% to about 1.2%, while the chlorine atomic concentration of the dielectric layer 184 may be 0%.

Because the dielectric material 182 may include addition elements, the dielectric layer 184 may include higher silicon atomic concentration and higher nitrogen atomic concentration than the dielectric material 182. In some embodiments, the silicon atomic concentration of the dielectric material 182 is in a range from about 29.3% to about 30.1%, while the silicon atomic concentration of the dielectric layer 184 may be about 43.7%. The nitrogen atomic concentration of the dielectric material 182 is in a range from about 30.5% to about 36.2%, while the nitrogen atomic concentration of the dielectric layer 184 may be about 55.9%. The above mentioned element concentration can be detected using energy dispersive X-ray (EDX) analysis.

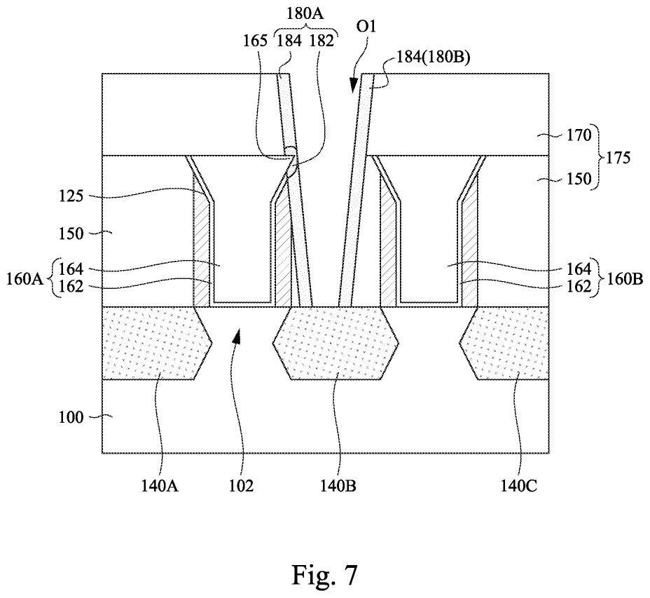

Reference is made to FIG. 7. An etching process is performed to the dielectric layer 184. In greater detail, the etching process may be an anisotropic etching, such as plasma dry etch, so as to remove the horizontal portions of the dielectric layer 184 from the top surface of the ILD structure 175 and from the top surface of the source/drain epitaxial structure 140B. The substantially vertical portions of the dielectric layer 184 may remain on sidewalls of the source/drain contact opening O1. In some embodiments, during the etching process, the substantially vertical portions of the dielectric layer 184 may also be shrunk, such that the dielectric material 182 is exposed to the source/drain contact opening O1. In some embodiments, the exposed surface of the dielectric material 182 may be coterminous with the exposed surface of the dielectric layer 184.

After the etching process is complete, dielectric liners 180A and 180B are formed. The dielectric liner 180A denotes to the liner (on the left side of FIG. 7) that includes the dielectric layer 184 and the dielectric material 182, and the dielectric liner 180B denotes to the liner (on the right side of FIG. 7) that only includes the dielectric layer 184. With respect to the dielectric liner 180A, the portion of the dielectric layer 184 below the dielectric material 182 can be referred to as a bottom portion of the dielectric liner 180A, the dielectric material 182 be referred to as a middle portion of the dielectric liner 180A, and the portion of the dielectric layer 184 above the dielectric material 182 can be referred to as a top portion of the dielectric liner 180A. In some embodiments, the middle portion of the dielectric liner 180A may include different composition than the top portion and the bottom portion of the dielectric liner 180A. The composition difference has been described above, and thus relevant details are not repeated for brevity. On the other hand, the dielectric material 182 is absent in the dielectric liner 180B. That is, an entirety of the dielectric liner 180B includes the dielectric layer 184, and thus the dielectric liner 180B may include substantially uniform composition throughout the dielectric liner 180B. Stated another way, the dielectric liner 180A may include greater oxygen concentration fluctuation than the dielectric liner 180B. In some embodiments, the dielectric liner 180A and the dielectric liner 180B have asymmetric profiles. For example, the dielectric liner 180B may include substantially a linear profile, while the dielectric liner 180A may include a non-linear profile.

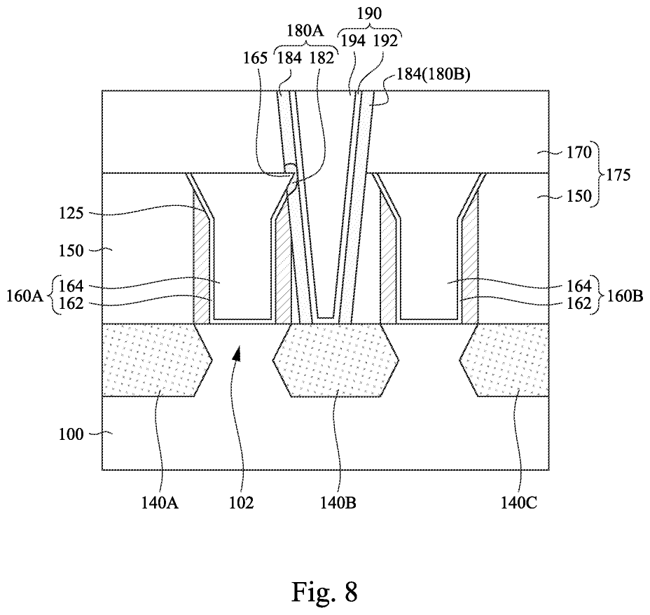

Reference is made to FIG. 8. A source/drain contact 190 is formed in the source/drain contact opening O1. In some embodiments, the source/drain contact 190 includes a diffusion barrier 192 and a plug 194. The source/drain contact 190 may be formed by, for example, depositing materials of the diffusion barrier 192 and the plug 194 in the source/drain contact opening O1, and then performing a planarization process, such as CMP to remove the excess materials. As a result, the top surface of the ILD structure 175, the top ends of the dielectric liners 180A and 180B, and the top surface of the source/drain contact 190 may be coplanar with each other. In some embodiments, both the dielectric layer 184 and the dielectric material 182 of the dielectric liner 180A may be in contact with the source/drain contact 190.

The diffusion barrier 192 may assist with the deposition of plug 194 and helps to reduce diffusion of a material of plug 194 through the dielectric liners 180A and 180B. In some embodiments, the diffusion barrier 192 includes titanium (Ti), titanium nitride (TiN), tantalum (Ta), tantalum nitride (TaN), or another suitable material. The plug 194 includes a conductive material, such tungsten (W), copper (Cu), aluminum (Al), ruthenium (Ru), cobalt (Co), molybdenum (Mo), nickel (Ni), or other suitable conductive material.

Based on the process as discussed in FIGS. 1 to 8, it can be seen that after the etching process of FIG. 4 is complete, the top corner 165 of the gate metal 164 of the metal gate structure 160A may be exposed. The dielectric material 182 is then selective formed covering the top corner 165 of the gate metal 164 of the metal gate structure 160A, and the dielectric layer 184 is then formed over the dielectric material 182. During the etching process as described in FIG. 7, the dielectric material 182 may act as a protective layer to prevent the top corner 165 of the gate metal 164 of the metal gate structure 160A from being exposed after the etching process is complete. As a result, the top corner 165 of the gate metal 164 of the metal gate structure 160A may be spaced apart from the following formed source/drain contact 190 through the dielectric material 182. If the dielectric material 182 is absent, the dielectric layer 184 may not be thick enough to protect the top corner 165 of the gate metal 164, and the top corner 165 of the gate metal 164 may be exposed after the etching process is complete. Accordingly, the source/drain contact 190 may be in contact with the top corner 165 of the gate metal 164 of the metal gate structure 160A, and current leakage may occur. Accordingly, the dielectric material 182 may act as a protective layer the prevent current leakage from the source/drain contact 190 to the metal gate structure 160A, which in turn will improve the device performance.

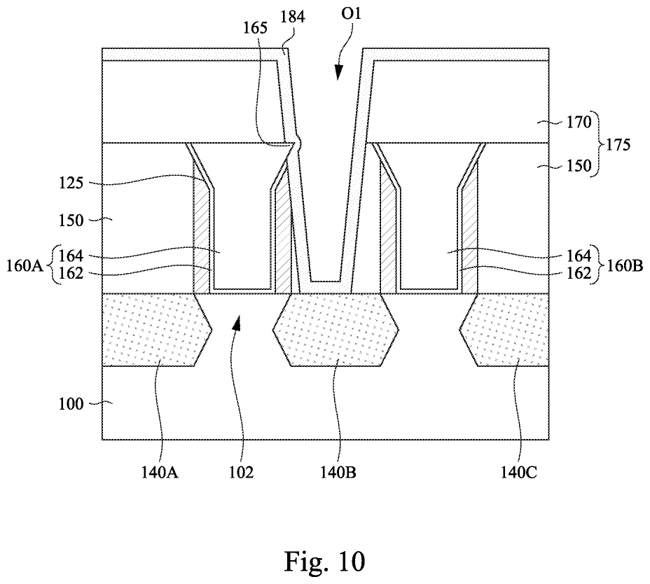

FIGS. 10 to 13 illustrate a method for manufacturing a semiconductor device at various stages in accordance with some embodiments of the present disclosure. The process as described in FIGS. 10 to 13 is different from the process as described in FIGS. 1 to 8, in that the dielectric material 182 is formed after the dielectric layer 184, and details will be discussed below. It is noted that some elements of FIGS. 10 to 13 have been described with respect to FIGS. 1 to 8, such elements are labeled the same and relevant details will not be repeated for brevity.

Reference is made to FIG. 10. A dielectric layer 184 is deposited over the structure shown in FIG. 4. In greater detail, the dielectric layer 184 is deposited in a conformal manner, such that the dielectric layer 184 is formed lining the exposed surfaces of the ILD structure 175, the exposed surface of the top corner 165 of the gate metal 164 of the metal gate structure 160A, and the top surface of the source/drain epitaxial structure 140B. In some embodiments, the dielectric layer 184 may wrap the top corner 165 of the gate metal 164 of the metal gate structure 160A.

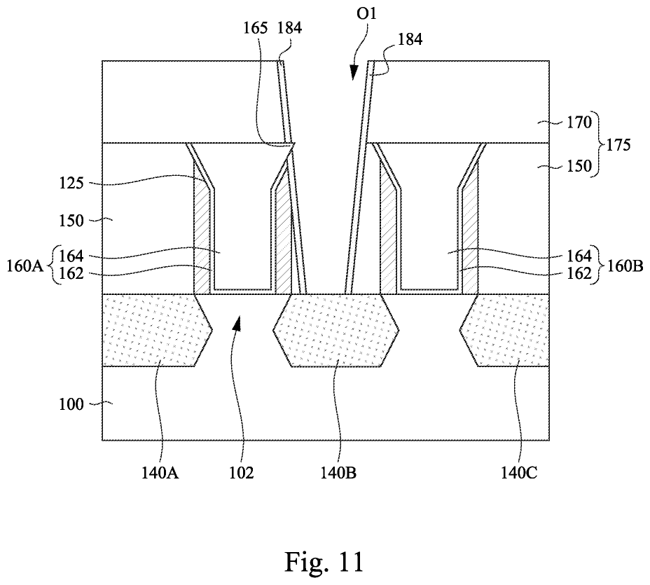

Reference is made to FIG. 11. An etching process is performed to the dielectric layer 184. In greater detail, the etching process may be an anisotropic etching, such as plasma dry etch, so as to remove the horizontal portions of the dielectric layer 184 from the top surface of the ILD structure 175 and from the top surface of the source/drain epitaxial structure 140B. The substantially vertical portions of the dielectric layer 184 may remain on sidewalls of the source/drain contact opening O1. In some embodiments, during the etching process, the substantially vertical portions of the dielectric layer 184 may also be shrunk, such that top corner 165 of the gate metal 164 of the metal gate structure 160A may be exposed to the source/drain contact opening O1. That is, the top corner 165 of the gate metal 164 of the metal gate structure 160A may protrude from the dielectric layer 184 and extend toward the source/drain contact opening O1.

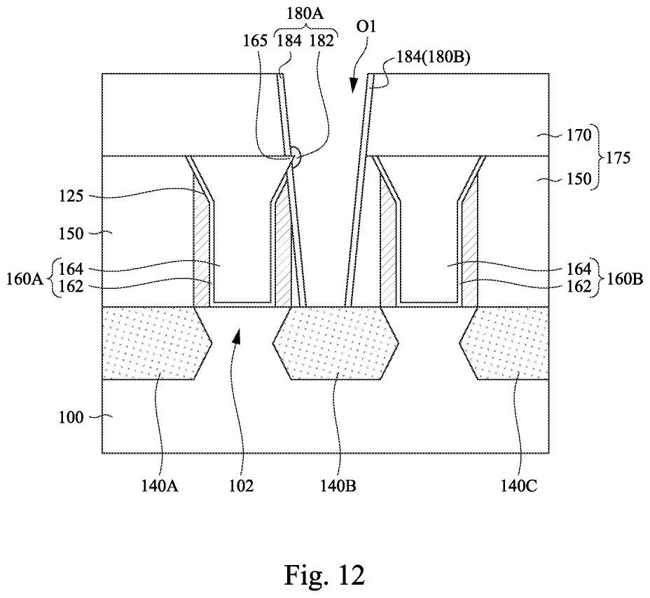

Reference is made to FIG. 12. An area selective deposition (ASD) process is performed to form a dielectric material 182 covering the exposed top corner 165 of the gate metal 164 of the metal gate structure 160A. The ASD process is performed such that the dielectric material 182 is selectively deposited on the exposed surface of the top corner 165 of the gate metal 164 of the metal gate structure 160A. In greater detail, the material of the dielectric material 182 may include a higher deposition rate on a metal surface than on a dielectric surface. That is, the material of the dielectric material 182 may include a higher deposition rate on the exposed surface of the top corner 165 of the gate metal 164 of the metal gate structure 160A than on the exposed surface of the dielectric layer 184. In some embodiments, the dielectric material 182 may include a ball-like cross-sectional view than wraps the top corner 165 of the gate metal 164 of the metal gate structure 160A.

The formation of the dielectric material 182 is described in FIGS. 9A to 9D. For example, a surface treatment (see FIG. 9A) is performed to the structure shown in FIG. 11. During the surface treatment, oxidation process and reduction process may occur at the same time but at different locations. In some embodiments, the exposed surfaces of the dielectric layer 184 may undergo an oxidation process during the surface treatment, such that a silicon oxide (SiO₂) layer is formed along the exposed surfaces of dielectric layer 184. The exposed surface of the top corner 165 of the gate metal 164 of the metal gate structure 160A may undergo a reduction process, resulting the exposed surface of the gate metal 164 substantially a pure metal layer.

A surface passivation (see FIG. 9B) is performed after the surface treatment is complete. During the surface passivation, the exposed surfaces of the dielectric layer 184 are oxidized to form a silicon oxide (SiO₂) surface. The WF₆ gas used in the surface passivation may react with the silicon oxide (SiO₂) surface of the ILD structure 175 by replacing the Si—O bonds with Si—F bonds.

An annealing process (see FIG. 9C) is performed after the surface passivation is complete. The annealing process is performed to reduce moisture (e.g., water, H₂O), in the structure shown in FIG. 11.

A thermal atomic layer deposition (ALD) process is performed after the annealing process is complete, so as to form the dielectric material 182 selectively on the exposed surface of the top corner 165 of the gate metal 164 of the metal gate structure 160A. As mentioned above, the exposed surfaces of the exposed surfaces of the dielectric layer 184 are oxidized to form a silicon oxide surface, and the silicon oxide surface is passivated by replacing the Si—O bonds at the silicon oxide surface with Si—F bonds. Because the Si—F bonds include stronger bonding energy, the precursors for depositing the dielectric material 182 are hard to react with the Si—F bonds at the surfaces of the dielectric layer 184. Stated another way, the Si—F bonds at the surfaces of the dielectric layer 184 may inhibit the deposition rate of the dielectric material 182. As a result, the Si—F bonds at the surfaces of the dielectric layer 184 may act as inhibitors that block the surfaces of the dielectric layer 184, such that the material of the dielectric material 182 may be selectively deposited on the exposed surface of the gate metal 164 of the metal gate structure 160A. Accordingly, the dielectric material 182 can be deposited in an area selective deposition manner, and the resulting structure is shown in FIG. 12.

After the etching process is complete, dielectric liners 180A and 180B are formed. The dielectric liner 180A denotes to the liner (on the left side of FIG. 12) that includes the dielectric layer 184 and the dielectric material 182, and the dielectric liner 180B denotes to the liner (on the right side of FIG. 12) that only includes the dielectric layer 184. With respect to the dielectric liner 180A, the portion of the dielectric layer 184 below and in contact with the top corner 165 of the gate metal 164 of the metal gate structure 160A can be referred to as a bottom portion of the dielectric liner 180A and the portion of the dielectric layer 184 above and in contact with the top corner 165 of the gate metal 164 of the metal gate structure 160A can be referred to as a top portion of the dielectric liner 180A. The dielectric material 182 can be referred to as a protrusion portion that protrudes toward the source/drain contact opening O1. The protrusion portion of the dielectric liner 180A wraps the top corner 165 of the gate metal 164 of the metal gate structure 160A, and connects the top portion and the bottom portion of the dielectric liner 180A. In some embodiments, the protrusion portion of the dielectric liner 180A may include different composition than the top portion and the bottom portion of the dielectric liner 180A. The composition difference has been described above, and thus relevant details are not repeated for brevity. On the other hand, the dielectric material 182 is absent in the dielectric liner 180B. That is, an entirety of the dielectric liner 180B includes the dielectric layer 184, and thus the dielectric liner 180B may include substantially uniform composition throughout the dielectric liner 180B.

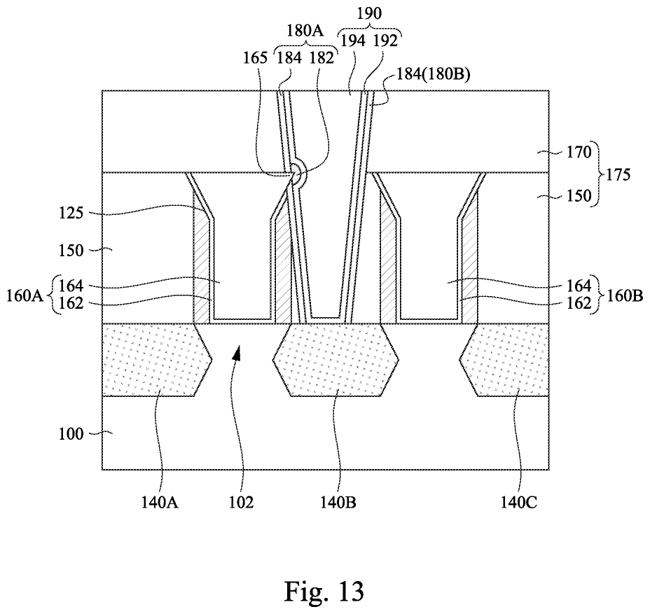

Reference is made to FIG. 13. A source/drain contact 190 is formed in the source/drain contact opening O1. In some embodiments, the source/drain contact 190 includes a diffusion barrier 192 and a plug 194. The diffusion barrier 192 may extend along the surface of the dielectric material 182, such that the dielectric material 182 of the dielectric liner 180A may protrude into the source/drain contact 190.

Based on the process as discussed in FIGS. 10 to 13, it can be seen that after the etching process of FIG. 11 is complete, the top corner 165 of the gate metal 164 of the metal gate structure 160A is exposed. The dielectric material 182 is then selective formed covering the top corner 165 of the gate metal 164 of the metal gate structure 160A. As a result, the top corner 165 of the gate metal 164 of the metal gate structure 160A may be spaced apart from the following formed source/drain contact 190 through the dielectric material 182. If the dielectric material 182 is absent, the source/drain contact 190 may be in contact with the top corner 165 of the gate metal 164 of the metal gate structure 160A, and current leakage may occur. Accordingly, the dielectric material 182 may act as a protective layer the prevent current leakage from the source/drain contact 190 to the metal gate structure 160A, which in turn will improve the device performance.

Based on the above discussion, it can be seen that the present disclosure offers advantages. It is understood, however, that other embodiments may offer additional advantages, and not all advantages are necessarily disclosed herein, and that no particular advantages is required for all embodiments. Embodiments of the present disclosure provide a method by forming a dielectric material selectively on an exposed surface of a top corner of gate structure. The dielectric material may act as a protective layer to prevent the top corner of gate structure from being in contact with the following formed source/drain contact and to further prevent current leakage. With such configuration, the device performance can be improved.

In some embodiments of the present disclosure, a semiconductor device includes a substrate. A gate structure is over the substrate. Source/drain epitaxial structures are on opposite sides of the gate structure. An interlayer dielectric (ILD) structure surrounds and covers the gate structure. A dielectric liner lines a sidewall of the ILD structure and wraps a top corner of the gate structure. The dielectric liner comprises a bottom portion, a top portion above the bottom portion, and a middle portion connecting the bottom portion and the top portion, wherein the middle portion has a different composition than the bottom portion and the top portion.

In some embodiments, the bottom portion and the top portion have a same composition.

In some embodiments, the bottom portion, the top portion, and the middle portion comprise silicon nitride, and the middle portion has a higher oxygen atomic concentration than the bottom portion and the top portion.

In some embodiments, the middle portion is in contact with the top corner of the gate structure.

In some embodiments, the bottom portion and the top portion are spaced apart from the top corner of the gate structure.

In some embodiments, the bottom portion and the top portion are in contact with the top corner of the gate structure.

In some embodiments, tungsten element and fluorine element are detectable at an interface between the top corner of the gate structure and the dielectric liner.

In some embodiments, the semiconductor device further includes a source/drain contact electrically connected to one of the source/drain epitaxial structures, wherein the dielectric liner lines a sidewall of the source/drain contact.

In some embodiments of the present disclosure, a semiconductor device includes a substrate. A gate structure is over the substrate. Source/drain epitaxial structures are on opposite sides of the gate structure. A source/drain contact is electrically connected to one of the source/drain epitaxial structure. A first dielectric liner lines a first sidewall of the source/drain contact. The first dielectric liner comprises a bottom portion, a top portion above the bottom portion, and a middle portion connecting the bottom portion and the top portion, wherein the middle portion has a higher oxygen atomic concentration than the bottom portion and the top portion.

In some embodiments, the middle portion has a lower silicon atomic concentration and a lower nitrogen atomic concentration than the bottom portion and the top portion.

In some embodiments, the middle portion of the first dielectric liner is in contact with a top corner of the gate structure.

In some embodiments, tungsten element and fluorine element are detectable at an interface between the top corner of the gate structure and the middle portion of the first dielectric liner.

In some embodiments, the middle portion of the first dielectric liner protrudes into the source/drain contact.

In some embodiments, the semiconductor device further includes a second dielectric liner lining a second sidewall of the source/drain contact, wherein the second dielectric liner and the first dielectric liner has asymmetric profiles.

In some embodiments, the semiconductor device further includes a second dielectric liner lining a second sidewall of the source/drain contact, wherein the first dielectric liner has a greater oxygen concentration fluctuation than the second dielectric liner.

In some embodiments of the present disclosure, a method includes forming a gate structure over a substrate; source/drain epitaxial structures over the substrate and on opposite sides of the gate structure; forming an interlayer dielectric (ILD) structure laterally surrounding and covering the gate structure; etching the ILD structure to form a source/drain contact opening exposing one of the source/drain epitaxial structures, wherein a top corner of the gate structure is exposed through the source/drain contact opening; selective depositing a dielectric material wraps the top corner of the gate structure; depositing a dielectric layer lining the source/drain contact; and forming a source/drain contact in the source/drain contact opening.

In some embodiments, selective depositing the dielectric material is performed prior to depositing the dielectric layer.

In some embodiments, selective depositing the dielectric material is performed after depositing the dielectric layer.

In some embodiments, the dielectric layer is in contact with the ILD structure.

In some embodiments, the method further includes etching the dielectric layer to expose the one of the source/drain epitaxial structures prior to forming the source/drain contact.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a substrate;
a gate structure over the substrate;
source/drain epitaxial structures on opposite sides of the gate structure;
an interlayer dielectric (ILD) structure surrounding and covering the gate structure; and
a dielectric liner lining a sidewall of the ILD structure and wrapping a top corner of the gate structure, wherein the dielectric liner comprises:
a bottom portion;
a top portion above the bottom portion; and
a middle portion connecting the bottom portion and the top portion, wherein the middle portion has a different composition than the bottom portion and the top portion.

2. The semiconductor device of claim 1, wherein the bottom portion and the top portion have a same composition.

3. The semiconductor device of claim 1, wherein the bottom portion, the top portion, and the middle portion comprise silicon nitride, and the middle portion has a higher oxygen atomic concentration than the bottom portion and the top portion.

4. The semiconductor device of claim 1, wherein the middle portion is in contact with the top corner of the gate structure.

5. The semiconductor device of claim 4, wherein the bottom portion and the top portion are spaced apart from the top corner of the gate structure.

6. The semiconductor device of claim 4, wherein the bottom portion and the top portion are in contact with the top corner of the gate structure.

7. The semiconductor device of claim 1, wherein tungsten element and fluorine element are detectable at an interface between the top corner of the gate structure and the dielectric liner.

8. The semiconductor device of claim 1, further comprising a source/drain contact electrically connected to one of the source/drain epitaxial structures, wherein the dielectric liner lines a sidewall of the source/drain contact.

9. A semiconductor device, comprising:
a substrate;
a gate structure over the substrate;
source/drain epitaxial structures on opposite sides of the gate structure;
a source/drain contact electrically connected to one of the source/drain epitaxial structure
a first dielectric liner lining a first sidewall of the source/drain contact, wherein the first dielectric liner comprises:
a bottom portion;
a top portion above the bottom portion; and
a middle portion connecting the bottom portion and the top portion, wherein the middle portion has a higher oxygen atomic concentration than the bottom portion and the top portion.

10. The semiconductor device of claim 9, wherein the middle portion has a lower silicon atomic concentration and a lower nitrogen atomic concentration than the bottom portion and the top portion.

11. The semiconductor device of claim 9, wherein the middle portion of the first dielectric liner is in contact with a top corner of the gate structure.

12. The semiconductor device of claim 11, wherein tungsten element and fluorine element are detectable at an interface between the top corner of the gate structure and the middle portion of the first dielectric liner.

13. The semiconductor device of claim 9, wherein the middle portion of the first dielectric liner protrudes into the source/drain contact.

14. The semiconductor device of claim 9, further comprising a second dielectric liner lining a second sidewall of the source/drain contact, wherein the second dielectric liner and the first dielectric liner has asymmetric profiles.

15. The semiconductor device of claim 9, further comprising a second dielectric liner lining a second sidewall of the source/drain contact, wherein the first dielectric liner has a greater oxygen concentration fluctuation than the second dielectric liner.

16. A method, comprising:
forming a gate structure over a substrate;
source/drain epitaxial structures over the substrate and on opposite sides of the gate structure;
forming an interlayer dielectric (ILD) structure laterally surrounding and covering the gate structure;
etching the ILD structure to form a source/drain contact opening exposing one of the source/drain epitaxial structures, wherein a top corner of the gate structure is exposed through the source/drain contact opening;
selective depositing a dielectric material wraps the top corner of the gate structure;
depositing a dielectric layer lining the source/drain contact; and
forming a source/drain contact in the source/drain contact opening.

17. The method of claim 16, wherein selective depositing the dielectric material is performed prior to depositing the dielectric layer.

18. The method of claim 16, wherein selective depositing the dielectric material is performed after depositing the dielectric layer.

19. The method of claim 16, wherein the dielectric layer is in contact with the ILD structure.

20. The method of claim 16, further comprising etching the dielectric layer to expose the one of the source/drain epitaxial structures prior to forming the source/drain contact.
